(19) United States
(12) Patent Application Publication
(10) Pub. No.: US 2008/0043145 A1
(43) Pub. Date: Feb. 21, 2008

(54) Image Processing Apparatus, Image Processing Method, and Image Display Apparatus

(76) Inventors: Jun Someya, Tokyo (JP); Akihiro Nagase, Tokyo (JP); Yoshiaki Okuno, Tokyo (JP)

Correspondence Address: BIRCH STEWART KOLASCH & BIRCH, PO BOX 747, FALLS CHURCH, VA, 22040-0747, US

(21) Appl. No.: 11/597,408

(22) PCT Filed: Oct. 19, 2004
(86) PCT No.: PCT/JP04/15397

§ 371 Date: Nov. 22, 2006

(30) Foreign Application Priority Data
Aug. 31, 2004 (JP) 2004-252212

(51) Int. Cl. H03L 7/00

(52) U.S. Cl. 348/538; 348/E07.012

(57) ABSTRACT

An object of the present invention is to provide an image processing apparatus and image processing method capable of obtaining better picture quality by appropriately improving the sharpness of edges of an image. In order to achieve the object, the image processing apparatus comprises a zoom ratio control means for detecting edges in image data and generating zoom ratio control values according to the widths of the detected edges; an edge width correction means for correcting the edge widths by carrying out an interpolation process on the image data according to the zoom ratio control values; an enhancement value calculation means for detecting high frequency components of the image data with the corrected edge widths, and calculating enhancement values for enhancing the edges of the image data according to the detected high frequency components; and an edge enhancement means for enhancing the edges of the image data by adding the enhancement values to the image data with the corrected edge widths.

### FIELD OF THE INVENTION

The present invention relates to an image processing apparatus for correcting image edges to a desired sharpness, an image processing apparatus capable of changing the number of image pixels by an arbitrary zoom ratio and correcting image edges to a desired sharpness, and an image display apparatus using these types of image processing apparatus.

### BACKGROUND ART

An example of an image processing method for correcting edges in an image to enhance their sharpness is disclosed in Japanese Patent Application Publication No. 2002-16820. This patent document describes an image processing method that calculates absolute values of derivatives of input image signals and the mean value of the absolute values, obtains difference values by subtracting the mean value from the calculated absolute values, and controls enlargement and reduction ratios of the image according to the difference values. By controlling the enlargement and reduction ratios of the image according to changes in image signals as described above, it is possible to make the rising and falling transitions of edges steeper by using image enlargement and reduction circuits, thereby improving the sharpness of the image.

Japanese Patent Application Publication No. 2000-101870 discloses an image processing method that, when converting the number of pixels in an input image, generates control values based on high frequency components of the image signal and uses the control values to control the interpolation phase in an interpolation filter used in the conversion of the number of pixels. Such control of the interpolation phase according to high frequency components produces sharper transitions at edges in the image, resulting in a crisper image.

A problem in the conventional image processing methods disclosed in the references cited above is that because the edge correction is carried out by using corrective values based on amounts of high frequency components in the image signal, it is difficult to improve the sharpness of edges at which the change in the level of the image signal is small. It is therefore difficult to improve the sharpness without overcorrecting or undercorrecting in the image as a whole. Another problem is that edge corrections made in the vertical direction by the conventional image processing methods require delay circuits for obtaining the pixel data necessary for the corrections and for adjusting the output timing of the corrected image data, making it difficult to reduce costs.

The present invention addresses the problems above with the object of providing an image processing apparatus and an image processing method capable of improving image quality by appropriate improvement of edge sharpness.

### DISCLOSURE OF THE INVENTION

A first image processing apparatus according to the present invention comprises an edge correction means for correcting edge widths in the image, an enhancement value calculation means for calculating enhancement values for enhancing edges according to high frequency components of the image with the corrected edge widths, and an edge enhancement means for enhancing the edges by adding the enhancement values to the image with the corrected edge widths.

A second image processing apparatus according to the present invention comprises a frame memory control means for writing luminance data and color difference data of an image into a frame memory and reading them at prescribed timings, and edge width correction means for extracting the data for a plurality of vertically aligned pixels from the luminance data read from the frame memory and correcting vertical edge widths in the extracted pixel data, wherein the frame memory control means reads the color difference data with a delay from the luminance data of at least the interval required for correction of the edge widths by the edge width correction means.

### BRIEF DESCRIPTION OF THE DRAWINGS

FIG. 1 is a block diagram showing an embodiment of the image processing apparatus of the present invention.

FIG. 2 is a block diagram showing the internal structure of the image processing apparatus.

FIG. 3 is a block diagram showing the internal structure of the frame memory controller.

FIGS. 4(a) and 4(b) are drawings illustrating the read and write timings of the frame memory.

FIG. 5 is a block diagram showing the internal structure of the vertical edge corrector.

FIG. 6 illustrates a pixel delay operation.

FIGS. 7(a) to 7(d) illustrate edge width correction processing.

FIG. 8 illustrates an edge width detection method.

FIG. 9 illustrates a pixel delay operation.

FIGS. 10(a) to 10(d) illustrate edge enhancement processing.

FIG. 11 is a block diagram showing an embodiment of an image processing apparatus according to the present invention.

FIG. 12 is a block diagram showing the internal structure of the edge width corrector.

FIG. 13 illustrates a pixel delay operation.

FIG. 14 illustrates a pixel delay operation.

FIG. 15 is a block diagram showing an embodiment of an image processing apparatus according to the present invention.

FIGS. 16(a) to 16(c) illustrate enlargement and reduction processing of an image in the pixel number converter.

FIGS. 17(a) and 17(b) illustrate a change in edge width due to enlargement processing.

FIG. 18 is a block diagram showing an embodiment of an image processing apparatus of the present invention.

FIG. 19 is a block diagram showing the internal structure of the image processor.

FIG. 20 is a block diagram showing the internal structure of the edge corrector.

FIGS. 21(a) to 21(e) illustrate image combination and image processing control signals.

### BEST MODE OF PRACTICING THE INVENTION

### First Embodiment

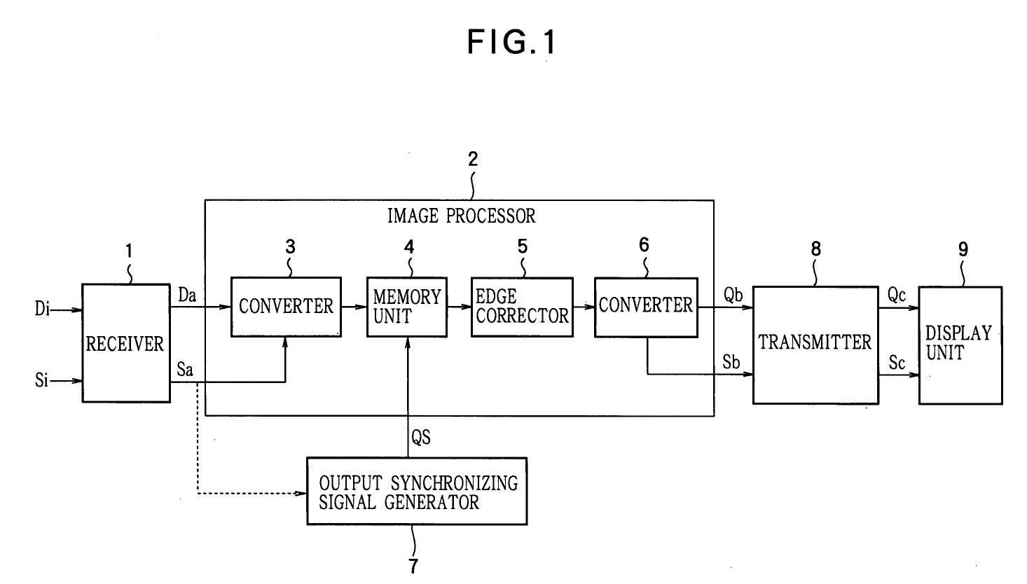

FIG. 1 is a block diagram showing an embodiment of an image display apparatus having image processing apparatus according to the present invention. The image display apparatus shown in FIG. 1 comprises a receiver 1, an image processor 2, an output synchronizing signal generator 7, a transmitter 8, and a display unit 9. The image processor 2 comprises a converter 3, a memory unit 4, an edge corrector 5, and another converter 6.

The receiver 1 receives an externally input image signal Di and a synchronizing signal Si, and converts the image signal Di to digital image data Da, which are output with a synchronizing signal Sa. If the image signal Di is an analog signal, the receiver 1 is configured as an A/D converter. If the image signal Di is a serial or parallel digital signal, the receiver 1 is configured as a receiver of the corresponding type, and may include a tuner if necessary.

The image data Da may comprise color data for the three primary colors red (R), green (G), and blue (B), or may comprise separate data for luminance and color components. In the following description, it will be assumed that the image data Da comprise red-green-blue trichromatic color data.

The image data Da and synchronizing signal Sa output from the receiver 1 are input to converter 3 in the image processor 2. The synchronizing signal Sa is also input to the output synchronizing signal generator 7.

Converter 3 converts the image data Da comprising red-green-blue trichromatic color data to luminance data DY and color difference data DCr, DCb. Converter 3 also delays the synchronizing signal Sa by the time required for this conversion of the image data Da, and outputs a delayed synchronizing signal DS. The luminance data DY, color difference data DCr, DCb, and synchronizing signal DS output from converter 3 are sent to the memory unit 4.

The memory unit 4 temporarily stores the luminance data DY and color difference data DCr, DCb output from converter 3. The memory unit 4 comprises a frame memory that is used as a frame rate conversion memory for converting image signals output from devices having different frame rates, such as personal computers and television sets, to an image signal having a fixed rate (for example, 60 Hz), or as a frame buffer for storing one frame of image data. The luminance data DY and color difference data DCr, DCb are stored in this frame memory.

The output synchronizing signal generator 7 generates a synchronizing signal QS indicating timings for reading the luminance data DY and color difference data DCr, DCb stored in the memory unit 4, and outputs it to the memory unit 4. When the frame rate is converted in the frame memory in the memory unit 4, to output image data from the memory unit 4 with a different frame rate from the frame rate of the image data Da, the output synchronizing signal generator 7 generates a synchronizing signal QS having a different frequency from the frequency of synchronizing signal Sa. When the frame rate is not converted in the memory unit 4, synchronizing signals QS and Sa are the same.

The memory unit 4 reads out the luminance data DY and color difference data DCr, DCb according to the synchronizing signal QS provided from the output synchronizing signal generator 7, and outputs timing-adjusted luminance data QY and color difference data QCr, QCb to the edge corrector 5. In doing so, the memory unit 4 delays the reading of the color difference data QCr, QCb to allow time for performing an edge correction on the luminance data QY.

The edge corrector 5 performs an edge correction on the luminance data QY read from the memory unit 4, and outputs the edge-corrected luminance data ZYb to converter 6 together with the color difference data QCr, QCb, which have been read from the memory unit 4 with the prescribed delay.

Converter 6 converts the luminance data ZYb and color difference data QCr, QCb to image data Qb in a format capable of being displayed by the display unit 9, and outputs the converted image data Qb to the transmitter 8. Specifically, converter 6 converts the image data comprising luminance data and color difference data to image data comprising red-green-blue trichromatic color data. This does not apply, however, when the data format receivable by the display unit 9 is not a trichromatic image data format; in that case, converter 6 converts the data to the appropriate format.

The display unit 9 displays the image data Qc output from the transmitter 8 at the timing indicated by a synchronizing signal Sc. The display unit 9 may include any type of display device, such as a liquid crystal panel, a plasma panel, a cathode ray tube (CRT), or an organic luminescence (EL) display device.

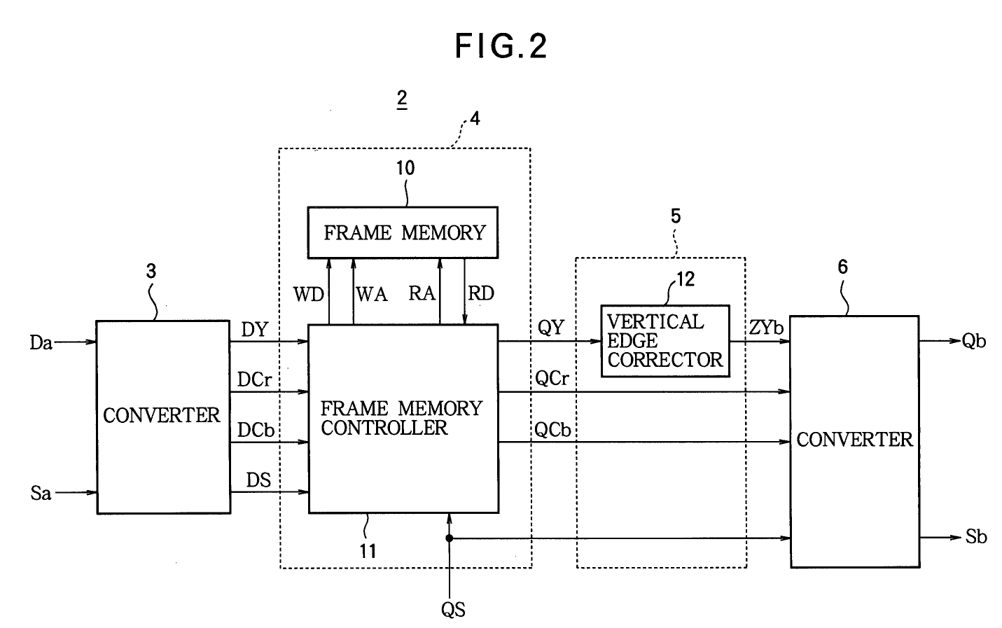

FIG. 2 is a block diagram showing the detailed internal structure of the image processor 2 in FIG. 1. As shown in FIG. 2, the memory unit 4 comprises a frame memory 10 and a frame memory controller 11. As noted above, the frame memory 10 is used as a frame rate conversion memory or as a frame buffer memory for storing the image data for one frame. Frame memories of the type found in typical image processing apparatus can be used as the frame memory 10. The edge corrector 5 has a vertical edge corrector 12.

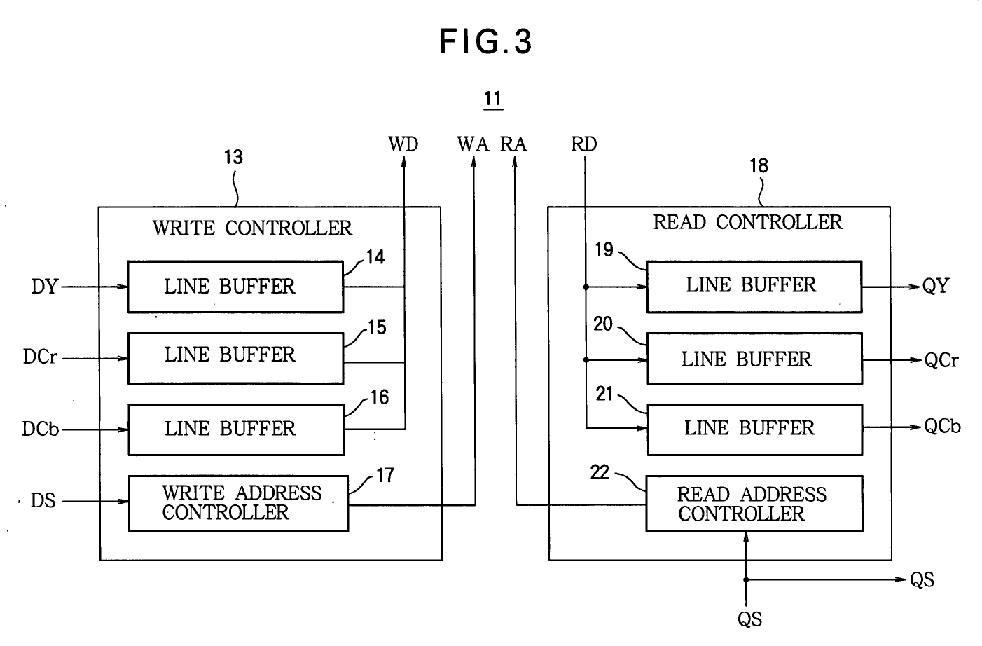

FIG. 3 is a block diagram showing the internal structure of the frame memory controller 11 in FIG. 2. As shown in FIG. 3, the frame memory controller 11 comprises a write controller 13 and a read controller 18. The write controller 13 comprises line buffers 14, 15, 16 and a write address controller 17; the read controller 18 comprises line buffers 19, 20, 21 and a read address controller 22.

The operation of the image processor 2 will now be described with reference to FIGS. 2 and 3.

Converter 3 converts the image data Da to luminance data DY and color difference data DCr, DCb, and outputs these data to the frame memory controller 11 in the memory unit 4. Simultaneously, converter 3 delays the synchronizing signal Sa by the time required for conversion of the image data Da, and outputs the delayed synchronizing signal DS to the frame memory controller 11.

The luminance data DY and color difference data DCr, DCb input to the frame memory controller 11 are supplied to respective line buffers 14, 15, 16 in the write controller 13. From the synchronizing signal DS, the write address controller 17 generates write addresses WA used when the luminance data DY and color difference data DCr, DCb input to the line buffers 14, 15, 16 are written into the frame memory 10. The write controller 13 sequentially reads out the luminance data DY and color difference data DCr, DCb stored in the line buffers, and writes them as image data WD into the frame memory 10 at the write addresses WA.

In the meantime, from the synchronizing signal QS output by the output synchronizing signal generator 7, the read address controller 22 generates read addresses RA for reading the luminance data DY and color difference data DCr, DCb written into the frame memory 10. The read addresses RA are generated so that the color difference data DCr, DCb are read with a delay from the luminance data DY equal to the interval required for edge correction by the edge corrector 5. The frame memory 10 outputs data RD read according the read addresses to the line buffers 19, 20, 21. The line buffers 19, 20, 21 output luminance data QY and color difference data QCr, QCb, the timings of which have been adjusted as above, to the edge corrector 5.

When DRAMs are used for the frame memory 10, for example, the operation carried out at any one time between the frame memory 10 and frame memory controller 11 is restricted to either writing or reading. Therefore, since the luminance data and color difference data for one line cannot be written or read continuously, a timing adjustment is performed whereby the line buffers 14, 15, 16 write continuous-time luminance data DY and color difference data DCr, DCb intermittently into the frame memory, and the line buffers 19, 20, 21 receive luminance data QY and color difference QCr, QCb read intermittently from the frame memory 10, but output them as continuous-time data.

The luminance data QY input to the edge corrector 5 are supplied to the vertical edge corrector 12. The vertical edge corrector 12 performs edge corrections in the vertical direction on the luminance data QY, and outputs the vertically edge-corrected luminance component data ZYb to converter 6. The edge correction operation in the vertical edge corrector 12 will be described later. This vertical edge correction produces a delay of a prescribed number of lines between the corrected luminance data ZYb and the uncorrected luminance data QY. If the delay is by k lines, the color difference data QCr, QCb input to converter 6 must also be delayed by k lines. The read address controller 22 generates read addresses RA so that the corrected luminance data ZYb and the color difference data QCr, QCb are input to converter 6 in synchronization with each other. That is, the read addresses RA are generated so that the color difference data QCr, QCb are read with a k-line delay from the luminance data QY.

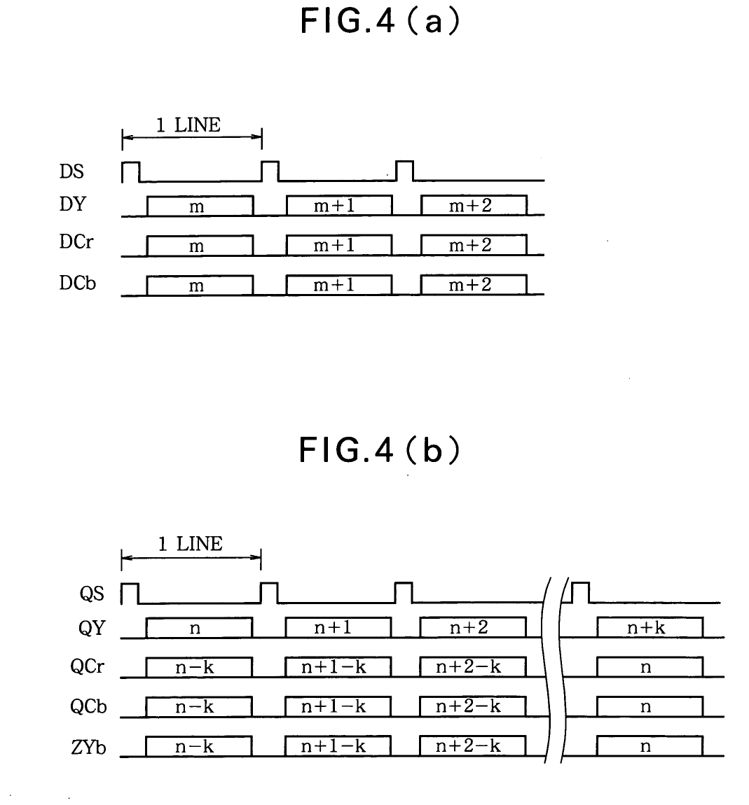

FIGS. 4(a) and 4(b) illustrate the read and write timings of the frame memory. FIG. 4(a) shows the luminance data DY and color difference data DCr, DCb written into the frame memory 10. FIG. 4(b) shows the luminance data DY and color difference data DCr, DCb read from the frame memory 10 and the luminance data ZYb after the edge correction. One-line periods of the synchronizing signals DS, QS are indicated in FIGS. 4(a) and 4(b).

As shown in FIG. 4(b), from the frame memory 10, the frame memory controller 11 reads color difference data QCr, QCb that precede the luminance data QY by k lines (that is, the color difference data QCr, QCb are read out with a k-line delay from the luminance data QY). Converter 6 thereby receives color difference data QCr, QCb synchronized with the luminance data ZYb. This scheme, in which the image data are converted to luminance data DY and color difference data DCr, DCb, which are written into the frame memory, the number of lines of luminance data necessary to perform an edge correction are read out, and the color difference data QCr, QCb are read out with a delay equivalent to the number of lines necessary for the edge correction process, reduces the amount of line memory required for the timing adjustment of the color difference data.

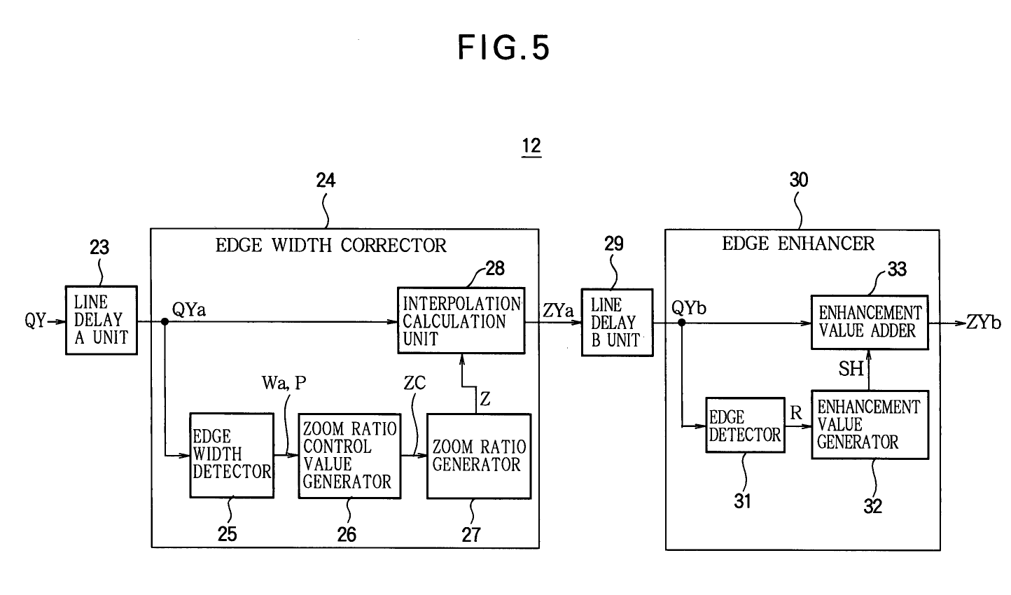

Next, the operation of the vertical edge corrector 12 will be described. FIG. 5 is a block diagram showing the internal structure of the vertical edge corrector 12. The vertical edge corrector 12 comprises a line delay A unit 23, an edge width corrector 24, a line delay B unit 29, and an edge enhancer 30. The edge width corrector 24 includes an edge width detector 25, a zoom ratio control value generator 26, a zoom ratio generator 27, and an interpolation calculation unit 28. The edge enhancer 30 includes an edge detector 31, an enhancement value generator 32, and an enhancement value adder 33.

The line delay A unit 23 receives the luminance data QY output from the frame memory controller 11, and outputs luminance data QYa for the number of pixels necessary for vertical edge width correction processing in the edge width corrector 24. If the edge width correction processing is performed using eleven vertically aligned pixels, the luminance data QYa include eleven pixel data values.

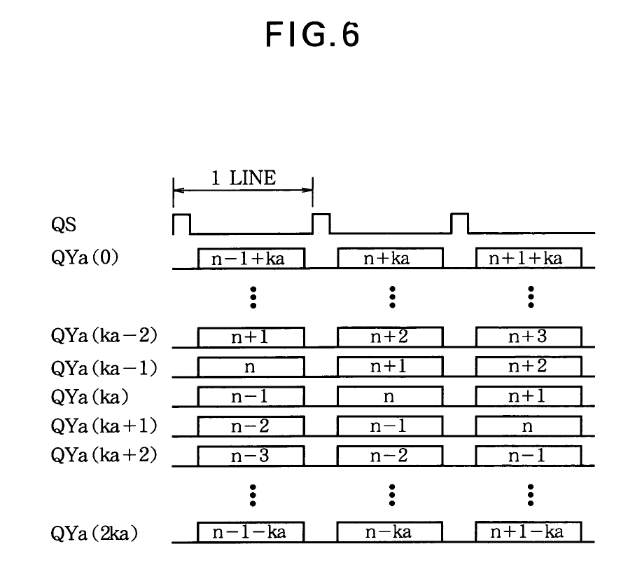

FIG. 6 shows a timing diagram of the luminance data QYa output from the line delay A unit 23, where the number of pixels in the luminance data QYa is assumed to be 2ka+1. The luminance data QYa output from the line delay A unit 23 are supplied to the edge width detector 25 and interpolation calculation unit 28.

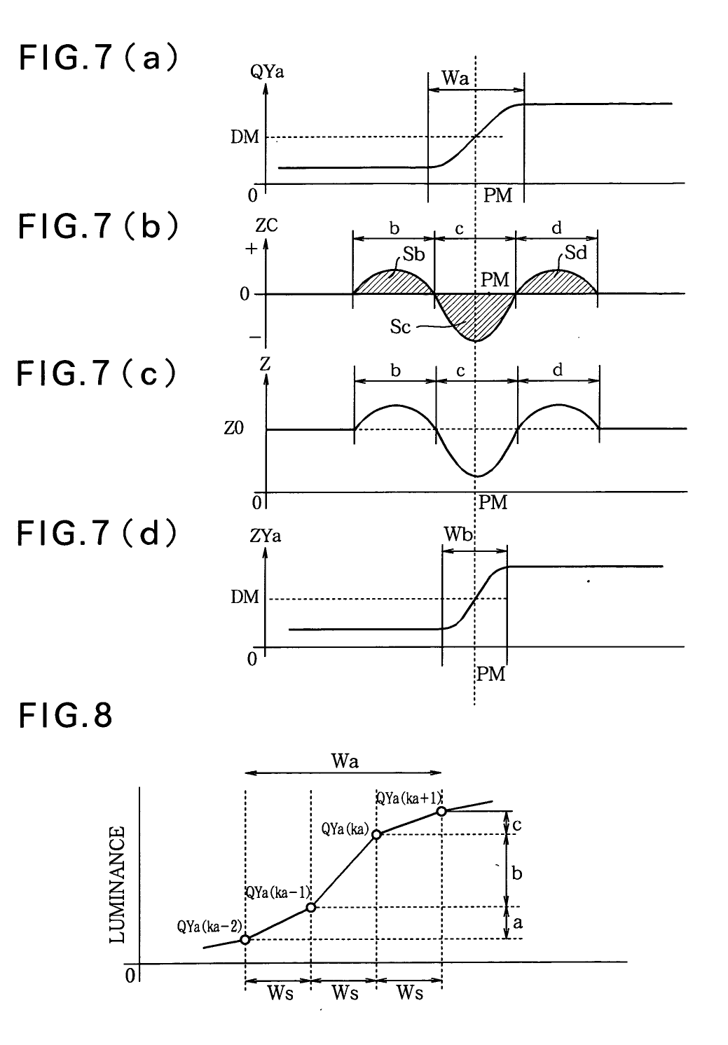

FIGS. 7(a) to 7(d) illustrate the edge width correction processing in the edge width corrector 24. The edge width detector 25 detects part of the luminance data QYa as an edge if the part changes continuously in magnitude in the vertical direction over a prescribed interval, detects the width Wa of the edge, and detects a prescribed position within the width as a reference position PM. FIG. 7(a) shows the edge width Wa and reference position PM detected by the edge width detector 25. The detected edge width Wa and reference position PM are input to the zoom ratio control value generator 26.

On the basis of the detected edge width Wa and reference position PM, the zoom ratio control value generator 26 outputs zoom ratio control values ZC used for edge width correction. FIG. 7(b) shows the zoom ratio control values. As shown in FIG. 7(b), the zoom ratio control values ZC are generated so that their values are positive in a front part of the edge (b), negative in a central part of the edge (c), positive in a rear part of the edge (d), and zero elsewhere, and sum to zero overall. The zoom ratio control values ZC are sent to the zoom ratio generator 27.

The zoom ratio generator 27 adds the zoom ratio control values ZC to a reference zoom conversion ratio Z0, which is a preset zoom conversion ratio that applies to the entire image, to generate zoom conversion ratios Z as shown in FIG. 7(c). The zoom conversion ratios Z are greater than the reference zoom conversion ratio Z0 in the front and rear parts of the edge (b and d), and smaller than the reference zoom conversion ratio Z0 in the central part of the edge (c) and their mean value is the reference zoom conversion ratio Z0. When this reference zoom conversion ratio Z0 is greater than unity (Z0>1), in addition to the edge width correction process, an enlargement process that increases the number of pixels is carried out; when Z0 is less than unity (Z0<1), a reduction process that decreases the number of pixels is carried out. When the reference zoom conversion ratio Z0 is equal to unity (Z0=1), only the edge correction process is carried out.

The interpolation calculation unit 28 carries out an interpolation process on the luminance data QYa according to the zoom conversion ratio Z. In the interpolation process, in the front part (b) and rear part (d) of the edge, in which the zoom conversion ratio Z is greater than the reference zoom conversion ratio Z0, the interpolation density is increased; in the central part (c) of the edge, in which the zoom conversion ratio Z is less than the reference zoom conversion ratio Z0, the interpolation density is decreased. Accordingly, an enlargement process that results in a relative increase in the number of pixels is performed in the front part (b) and rear part (d) of the edge, and a reduction process that results in a relative decrease in the number of pixels is performed in the central part (c) of the edge.

FIG. 7(d) illustrates luminance data ZYa after the pixel number conversion and edge width correction have been performed based on the zoom conversion ratio Z shown in FIG. 7(c). As shown in FIG. 7(d), the image is reduced in the central part (c) and enlarged in the front and rear parts (b and d) of the edge, thereby reducing the edge width, increasing the steepness of the luminance variation at the edge, and improving the sharpness of the image.

The zoom ratio control values ZC are generated according to the edge width Wa so as to sum to zero over these parts (b, c, and d). This means that if the areas of the hatched sectors in FIG. 7(b) are Sb, Sc, and Sd, respectively, the zoom ratio control values ZC are generated so that Sb+Sd=Sc. Accordingly, although the zoom conversion ratio values Z vary locally, the zoom conversion ratio Z of the image as a whole is identical to the reference zoom conversion ratio Z0. The zoom ratio control values ZC are thus generated so that the sum of the zoom conversion ratios Z becomes equal to the reference zoom conversion ratio Z0, whereby the edge width is corrected without causing any displacement of the image at the edge.

The corrected value of the edge width Wa, that is, the edge width Wb after the conversion, can be arbitrarily set by the magnitude of the zoom conversion ratio Z shown in FIG. 7(c), specifically by the size of the area Sc defined by the zoom conversion ratio control value ZC in the central part of the edge (c) shown in FIG. 7(b). Therefore, the size of area Sc can be adjusted to obtain the desired degree of crispness in the converted image.

FIG. 8 illustrates the relationship between the luminance data QYa and the edge width Wa. QYa(ka−2), QYa(ka−1), QYa(ka), QYa(ka+1) are pixel data constituting part of the luminance data QYa. Ws indicates the pixel data spacing (the vertical sampling period). The difference (a) between pixel data QYa(ka−2) and QYa(ka−1), the difference (b) between pixel data QYa(ka−1) and QYa(ka), and the difference (c) between pixel data QYa(ka) and QY(ka+1) are shown: specifically, a=QYa(ka−1)−QYa(ka−2), b=QYa(ka)−QYa(ka−1), and c=QYa(ka+1)−QYa(ka). The differences (a, b, c) indicate the variations of the pixel data in the front, central, and rear parts of the edge, respectively.

The edge width detector 25 detects as an edge a part of the image in which the luminance data increase or decrease monotonically and the front and rear parts are flatter than the central part. This condition means that each of the difference quantities (a, b, c) has the same positive or negative sign, or has a zero value, and the absolute values of a and c are smaller than the absolute value of b. More specifically, when these values (a, b, c) satisfy both of the following conditions (1a and 1b), the four pixels with the pixel data QYa(ka−2), QYa(ka−1), QYa(ka), QYa(ka+1) shown in FIG. 8 are detected as an edge, and the space they occupy is output as the edge width Wa.
da≧0, db≧0, dc≧0 or
da≦0, db≦0, dc≦0 (1a)
|db|>|da|, |db|>|dc| (1b)

In this case the edge width is three times the pixel spacing (Wa=3×Ws).

As shown in FIG. 6, the edge width detector 25 receives 2ka+1 pixel data values, so it can detect edges spanning up to 2ka+1 pixels and edge widths up to 2ka×Ws. The zoom ratio control value generator 26 can adjust the sharpness of the image responsive to the widths of edges by outputting different zoom conversion ratio control values according to the detected edge widths. Further, since the zoom conversion ratio control values are determined according to edge width instead of edge amplitude, the sharpness of even edges with gradual luminance variations can be enhanced.

Edge widths may also be detected by using pixel data extracted from every other pixel (at intervals of 2×Ws).

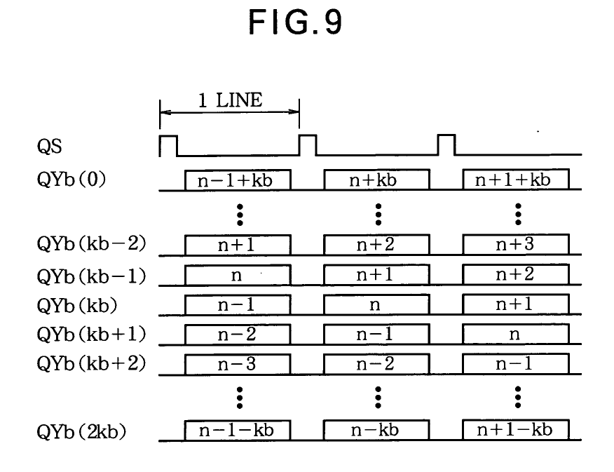

The luminance data ZYa with the corrected edge width output from the interpolation calculation unit 28 are sent to the line delay B unit 29. The line delay B unit 29 outputs luminance data QYb for the number of pixels necessary for edge enhancement processing in the edge enhancer 30. If the edge enhancement processing is performed using five pixels, the luminance data QYb comprise the luminance data of five pixels. FIG. 9 is a timing diagram of the luminance data QYb output from the line delay B unit 29, where the number of pixels in the luminance data QYb is assumed to be 2 kb+1. The luminance data QYb output from the line delay B unit 29 are input to the edge detector 31 and enhancement value adder 33.

The edge detector 31 performs a differential operation on the luminance data QYb, such as taking the second derivative, to detect luminance variations across edges with corrected edge widths Wb, and outputs the detection results to the enhancement value generator 32 as edge detection data R. The enhancement value generator 32 generates enhancement values SH for enhancing edges in the luminance data QYb according to the edge detection data R, and outputs the generated values SH to the enhancement value adder 33. The enhancement value adder 33 adds the enhancement values SH to the luminance data QYb to enhance edges therein.

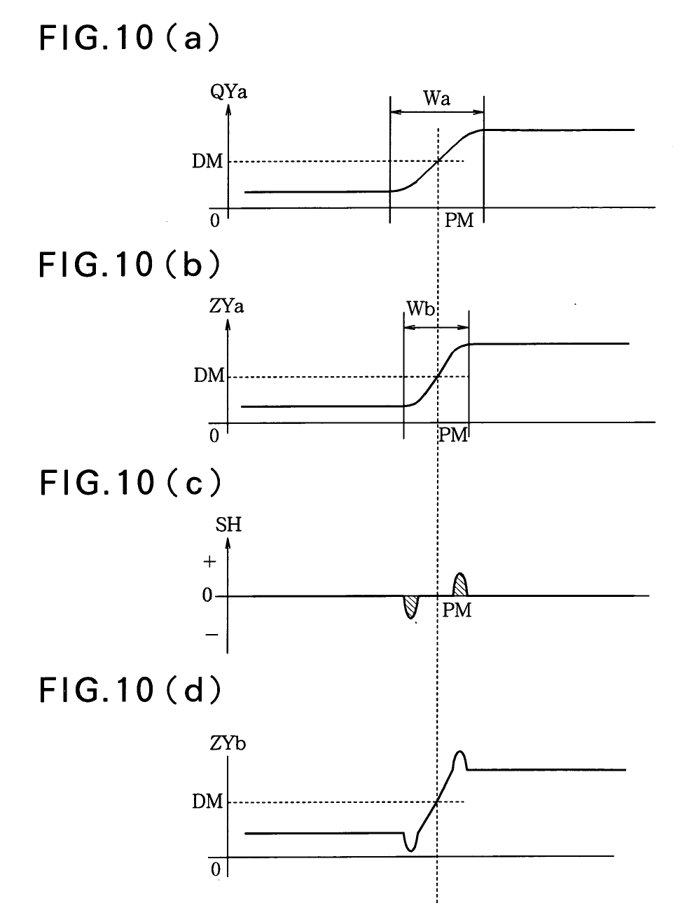

FIGS. 10(a) to 10(d) illustrate the edge enhancement processing in the edge enhancer 30. FIG. 10(a) shows the luminance data QYa before the edge width correction; FIG. 10(b) shows the luminance data ZYa after the edge width correction. FIG. 10(c) shows the enhancement values SH generated from the luminance data ZYa in FIG. 10(b); FIG. 10(d) shows the luminance data ZYb obtained from the edge enhancement, in which the enhancement values SH shown in FIG. 10(c) are added to the luminance data ZYa shown in FIG. 10(b).

As shown in FIG. 10(d), the edge enhancer 30 performs edge enhancement processing such that the enhancement values SH shown in FIG. 10(c), i.e., the undershoot and overshoot, are added to the front and rear parts of an edge having a width reduced by the edge width corrector 24. If the edge enhancement processing were to be performed without edge width correction, the differentiating circuit used for generating the undershoot and overshoot would have to have a low passband setting for edges having gradual luminance variations. The shapes of the undershoot and overshoot generated by a differentiating circuit with a low passband are widened, so edge sharpness cannot be sufficiently enhanced.

In the image processing apparatus according to the present invention, as shown in FIGS. 10(a) and 10(b), an edge width correction process is performed in which the edge width Wa of the luminance data QYa is reduced to obtain a steeper luminance variation at the edge. Then the undershoot and overshoot (enhancement values SH) shown in FIG. 10(c) are generated from the edge-corrected luminance data ZYa and added to the edge-corrected luminance data ZYa, so indistinct edges with wide widths can be properly modified to obtain a crisper image.

The edge enhancer 30 may be adapted so as not to enhance noise components, and may also include a noise reduction function that reduces noise components. This can be done by having the edge enhancement value generator 32 perform a nonlinear process on the edge detection data R output from the edge detector 31.

The edge detection data R obtained in the edge detector 31 may be detected by performing pattern matching or other calculations instead of by differentiation.

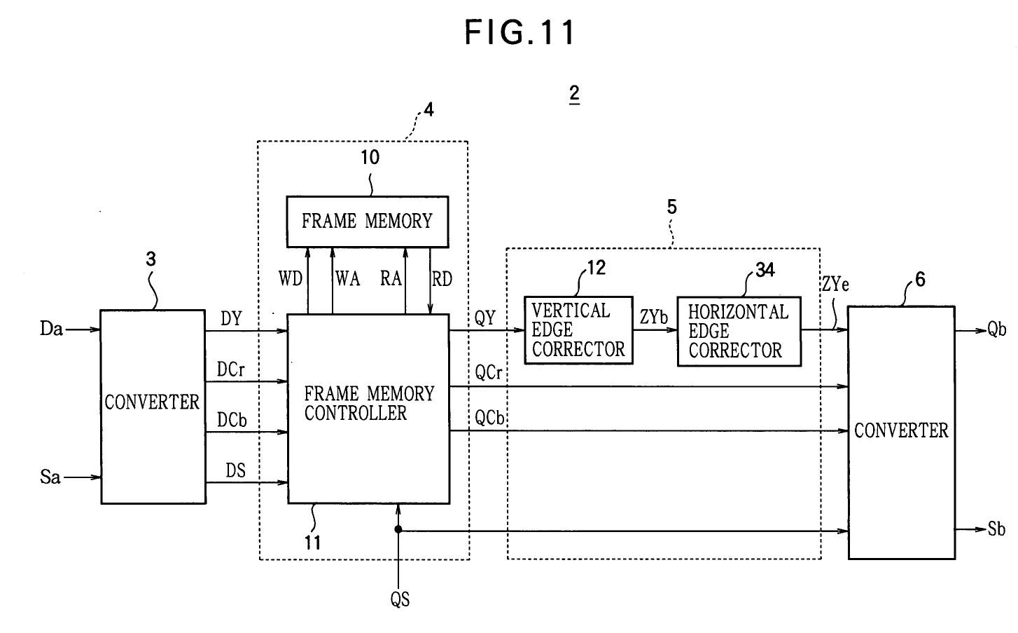

FIG. 11 is a block diagram showing an alternative internal structure of the image processor 2. The image processor 2 shown in FIG. 11 has a horizontal edge corrector 34 following the vertical edge corrector 12. The horizontal edge corrector 34 receives the luminance data ZYb output from the vertical edge corrector 12, and performs edge correction processing in the horizontal direction.

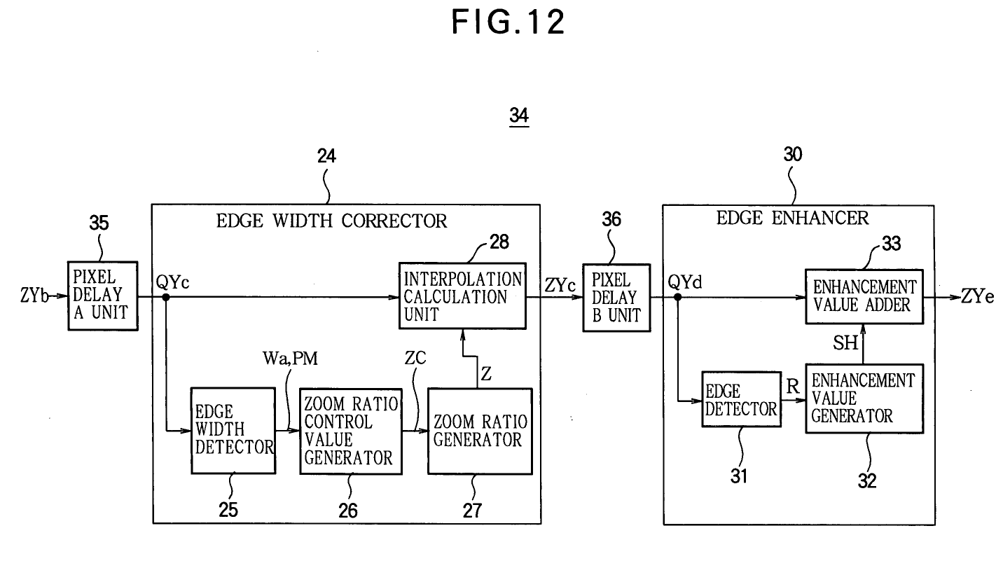

FIG. 12 is a block diagram showing the internal structure of the horizontal edge corrector 34. The structure and operation of the edge width corrector 24 and edge enhancer 30 in the horizontal edge corrector 34 are the same as in the vertical edge corrector 12 shown in FIG. 5.

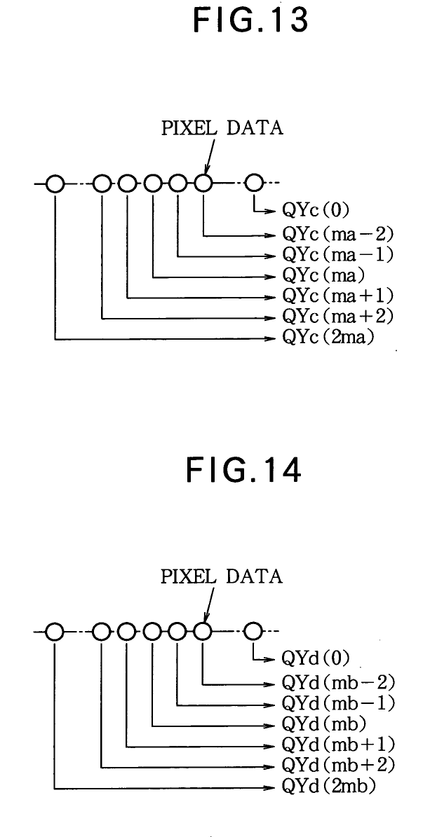

A pixel delay A unit 35 receives the luminance data ZYb sequentially output from the vertical edge corrector 12, and outputs luminance data QYc for the number of pixels necessary for horizontal edge width correction processing in the edge width corrector 24. FIG. 13 schematically illustrates the luminance data QYc output from the pixel delay A unit 35, where the number of pixels in the luminance data QYc is assumed to be 2ma+1. As shown in FIG. 13, the pixel delay A unit 35 outputs luminance data QYc comprising the values of a plurality of pixels aligned in the horizontal direction. If the edge width correction is performed using eleven horizontally aligned pixels, the luminance data QYc comprise eleven pixel data values.

The luminance data QYc for 2ma+1 pixels output from the pixel delay A unit 35 are sent to the edge width corrector 24. The edge width corrector 24 performs the same processing as for vertical edge width correction on the luminance data QYc in the horizontal direction, and outputs luminance data ZYc with corrected horizontal edge widths.

The luminance data ZYc with the corrected edge widths output from the edge width corrector 24 are input to a pixel delay B unit 36. The pixel delay B unit 36 outputs luminance data QYd for the number of pixels necessary for edge enhancement processing in the edge enhancer 30. FIG. 14 schematically illustrates the luminance data QYd output from the pixel delay B unit 36, where the number of pixels in the luminance data QYd is assumed to be 2 mb+1. As shown in FIG. 14, the pixel delay B unit 36 outputs luminance data QYd comprising the values of a plurality of pixels aligned in the horizontal direction. If the edge enhancement is performed using five pixels aligned in the horizontal direction, the luminance data QYd comprise five pixel data values.

The luminance data QYd of 2 mb+1 pixels output from the pixel delay B unit 36 are sent to the edge enhancer 30. The edge enhancer 30 performs the same processing on the luminance data QYd in the horizontal direction as was performed for edge enhancement in the vertical direction, and outputs luminance data ZYd with horizontally enhanced edges.

The luminance data ZYe with the corrected edges output from the horizontal edge corrector 34 are input to converter 6. The frame memory controller 11 outputs color difference data QCr, QCb with a delay equal to the interval of time required for the edge correction so that the color difference data QCr, QCb and luminance data ZYe with the corrected edges are input to converter 6 in synchronization with each other, the interval required for the edge correction including the necessary time, equivalent to a prescribed number of lines, from input of the luminance data QY to the vertical edge corrector 12 to output of the vertically edge-corrected luminance data ZYb and the necessary time, equivalent to a prescribed number of clock cycles, from input of the vertically edge-corrected luminance data ZYb to the horizontal edge corrector 34 to output of the horizontally edge-corrected luminance data ZYd. Specifically, read addresses RA are generated so that the color difference data QCr, QCb are output from the frame memory 10 with a delay from the luminance data ZYd equal to the above interval. The amount of line memory required for delaying the color difference data QCr, QCb can thereby be reduced.

The horizontal edge corrections may be performed before the vertical edge corrections, or the horizontal and vertical edge corrections may be performed concurrently.

In the invented image processing apparatus described above, when a vertical or horizontal edge correction is performed on an image, first the edge widths are corrected and then undershoots and overshoots are added to the edges with the corrected widths. Therefore, the widths of even edges having gradual luminance variations can be reduced to make the luminance variations steeper, and undershoots and overshoots having appropriate widths can be added. By performing adequate corrections on edges having various different luminance variations, it is possible to improve the sharpness of an image without overcorrecting or undercorrecting.

Further, when edge widths are corrected, since the corrections are determined by the widths of the edges instead of their amplitudes, the sharpness of even edges having gradual luminance variations is enhanced, so that adequate edge enhancement processing can be performed.

When an edge correction is performed, luminance data QY and color difference data QCr, QCb are written into a frame memory, edge correction processing is performed on the luminance data QY read from the frame memory, and the color difference data QCr, QCb are read with a delay from the luminance data QY equal to the interval required for the edge correction processing, so edge correction processing can be performed on the luminance data without providing delay elements necessary for a timing adjustment of the color difference data QCr, QCb.

### Second Embodiment

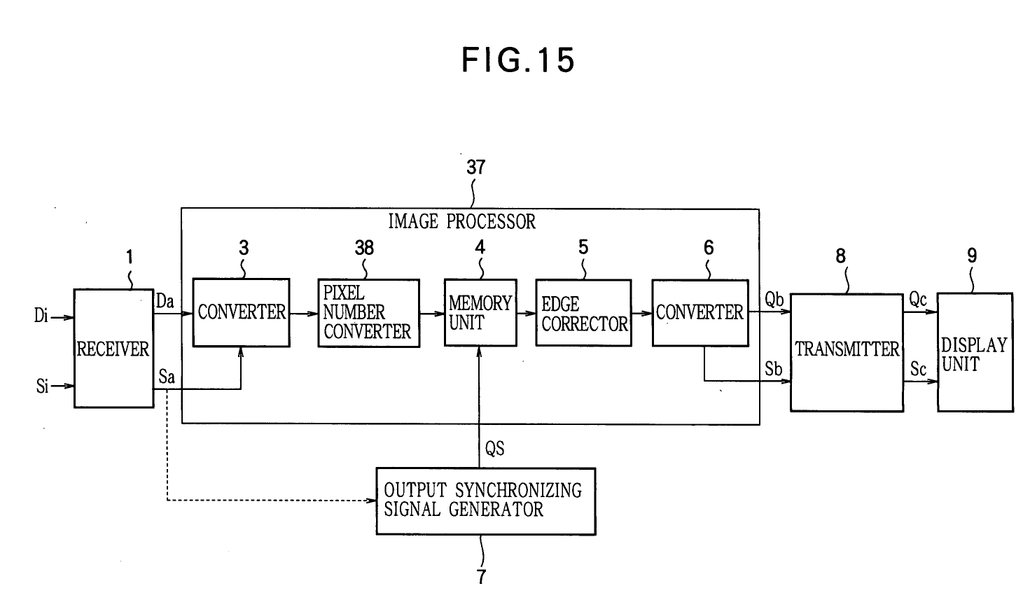

FIG. 15 is a block diagram showing another embodiment of the image processing apparatus according to the present invention. The image processing apparatus shown in FIG. 15 has a pixel number converter 38 between converter 3 and the memory unit 4; otherwise, the structure is the same as in the image processing apparatus described in the first embodiment (see FIG. 1).

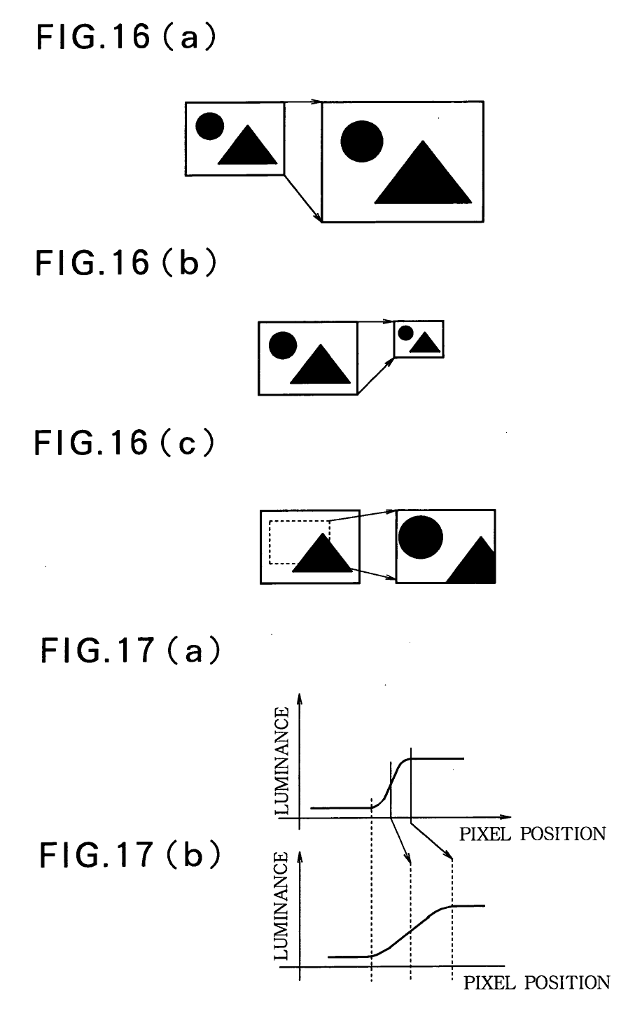

The pixel number converter 38 performs pixel number conversion processing, i.e., image enlargement or reduction processing, on image data comprising the luminance data DY and color difference data DCr, DCb output from converter 3. FIGS. 16(a), 16(b), and 16(c) show examples of enlargement processing, reduction processing, and partial enlargement processing of an image, respectively, in the pixel number converter 38.

When enlargement processing of an image is performed as shown in FIGS. 16(a) and 16(c), a problem of blurred edges occurs as described below. FIGS. 17(a) and 17(b) illustrate luminance changes at edges when enlargement processing of an image is performed, and illustrate the luminance changes at the edges of an input image and an enlarged image, respectively. As shown in FIG. 17(b), the enlargement processing results in an image with blurred edges due to increased edge width.

The image data on which enlargement or reduction processing has been performed are temporarily stored in the memory unit 4, then read out with a prescribed timing and sent to the edge corrector 5. The edge corrector 5 performs the edge correction process described in the first embodiment on the luminance data DY output from the memory unit 4, thereby correcting edges blurred by the enlargement processing.

According to the image processing apparatus of the present embodiment, since edges widened by enlargement processing of an image are corrected by the method described in the first embodiment, the image can be enlarged by an arbitrary ratio without reducing its sharpness. As in the first embodiment, it is also possible to add undershoots and overshoots having appropriate widths to the edges widened by the enlargement process, so that the sharpness of the enlarged image can be enhanced without overcorrecting or undercorrecting.

The enlargement or reduction processing of the image may also be performed before the image is converted to image data comprising luminance data and color difference data.

### Third Embodiment

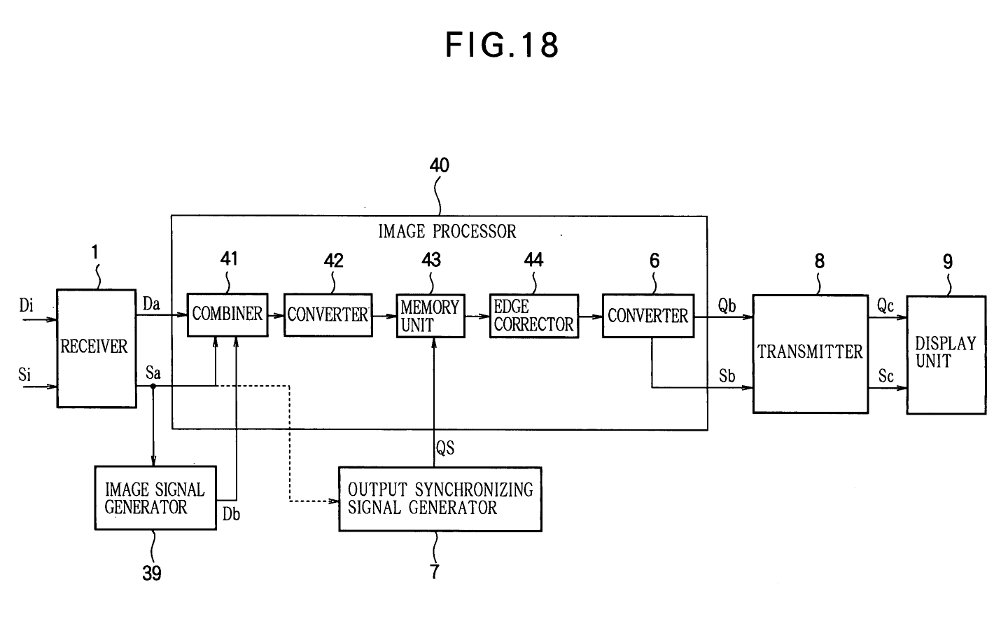

FIG. 18 is a block diagram showing another embodiment of the image processing apparatus according to the invention. The image processing apparatus shown in FIG. 18 further comprises an image signal generator 39 and a combiner 41. Operating with a prescribed timing based on the synchronizing signal Sa output from the receiver 1, the image signal generator 39 generates image data Db to be combined with the image data Da and outputs the image data Db to the combiner 41. The combiner 41 combines the image data Db with the image data Da. The image data Db will here be assumed to represent text information.

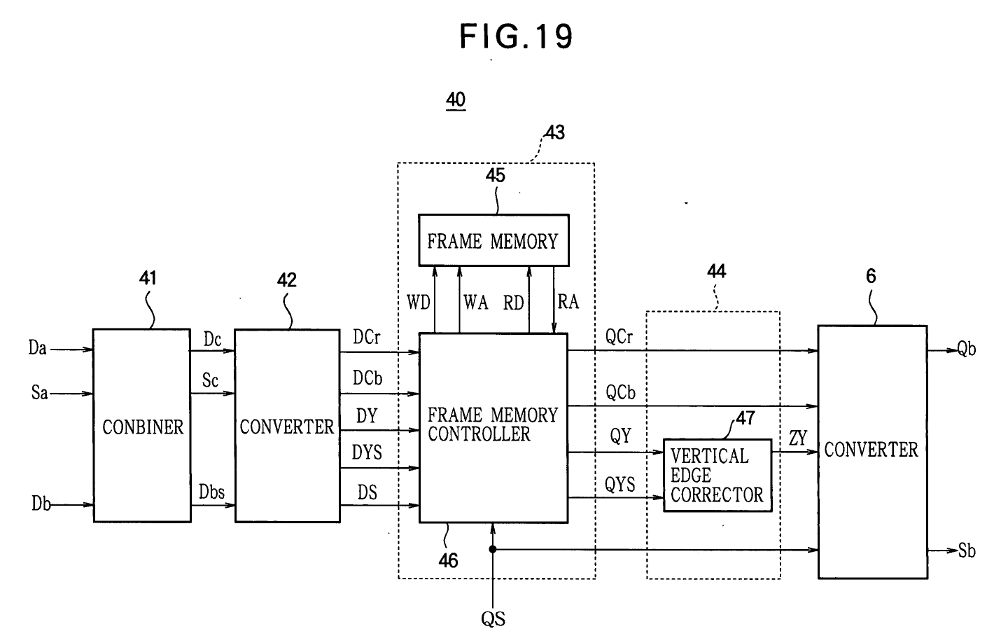

FIG. 19 is a block diagram showing the internal structure of the image processor 40. The combiner 41 generates combined image data Dc by selecting either image data Da or image data Db at every pixel, or by combining the two images by a calculation using the image data Da and image data Db. Simultaneously, the combiner 41 outputs a synchronizing signal Sc for the combined image data Dc and an image processing control signal Dbs designating an area in the combined image data Dc where edge correction processing is inhibited. Converter 42 converts the combined image data DC to luminance data DY and color difference data DCr, DCb as in the first embodiment, and outputs the data to a frame memory controller 46 together with an image processing control signal DYS and a synchronizing signal DS.

The frame memory controller 46 controls a frame memory 45 that temporarily stores the image processing control signal DYS, luminance data DY, and color difference data DCr, DCb. The frame memory controller 46 reads out the luminance data DY and color difference data DCr, DCb stored in the frame memory 45 with the timing shown in FIGS. 4(a) and 4(b), and outputs timing-adjusted luminance data QY and color difference data QCr, QCb. The frame memory controller 46 also outputs a timing-adjusted image processing control signal QYS by reading out the image processing control signal DYS temporarily stored in the frame memory 45 with a delay equal to the interval required for edge width correction processing in the vertical edge corrector 47. The luminance data QY and image processing control signal QYS output from the frame memory controller 46 are input to the vertical edge corrector 47.

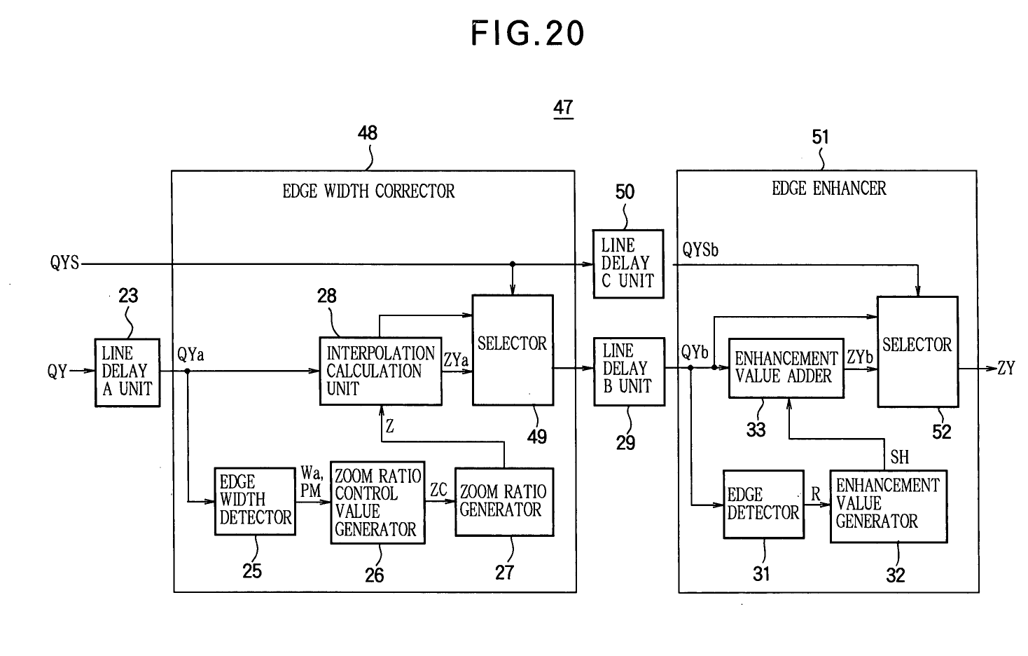

FIG. 20 is a block diagram showing the internal structure of the vertical edge corrector 47. The vertical edge corrector 47 shown in FIG. 20 has selectors 49, 52 in the edge width corrector 48 and edge enhancer 51 and a line delay C unit 50 between the edge width corrector 48 and edge enhancer 51. Otherwise, the structure is the same as in the first embodiment.

The interpolation calculation unit 28 performs vertical edge width correction processing on the vertically aligned luminance data QYa output from the line delay A unit 23, and outputs corrected luminance data ZYa. The corrected luminance data ZYa are sent to selector 49 together with the uncorrected luminance data QYa and the image processing control signal QYS. For every pixel, according to the image processing control signal QYS, selector 49 selects either the edge-width-corrected luminance data ZYa or the uncorrected luminance data QYa, and outputs the selected data to the line delay B unit 29.

The line delay B unit 29 outputs luminance data QYb, for the number of pixels necessary for edge enhancement processing in the edge enhancer 51, to the edge detector 31 and enhancement value adder 33. The line delay C unit 50 delays the image processing control signal QYS by an interval equivalent to the number of lines necessary for the processing performed in the edge enhancer 51, and outputs the delayed image processing control signal QYSb to selector 52.

The enhancement value adder 33 outputs luminance data ZYb obtained by performing an edge enhancement process on the luminance data QYb in the vertical direction output from the line delay B unit 29. The edge-enhanced luminance data ZYb are sent to selector 52 together with the unenhanced luminance data QYb and the image processing control signal QYSb delayed by the line delay C unit 50. For every pixel, according to the image processing control signal QYSb, selector 52 selects either the edge-enhanced luminance data ZYb or the unenhanced luminance data QYb and outputs the selected data as luminance data ZY.

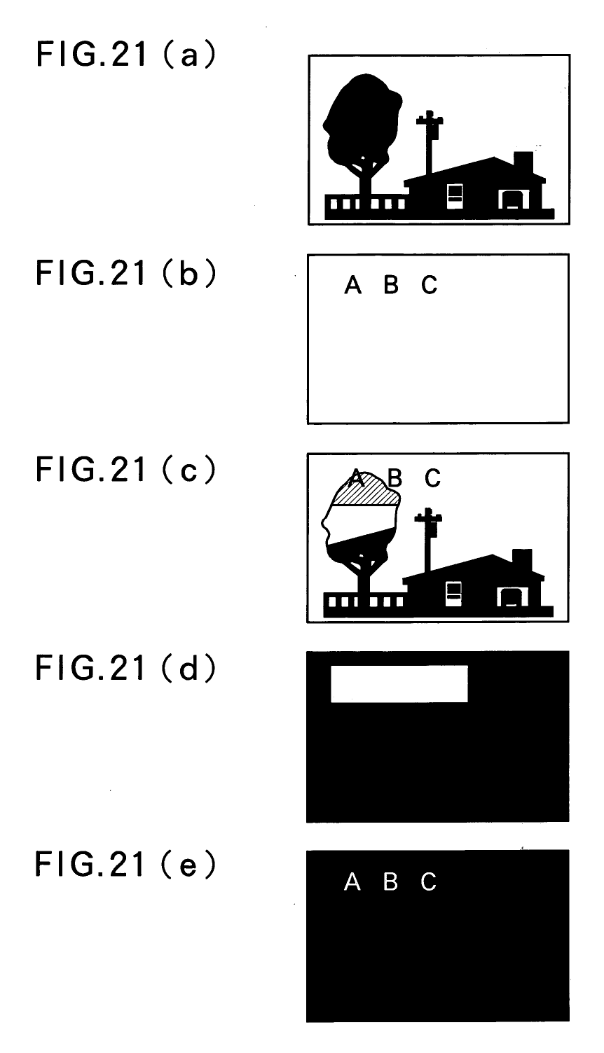

FIGS. 21(a) to 21(e) illustrate the operation of the image processing apparatus according to the present embodiment. FIGS. 21(a) to 21(c) show examples of the image data Da, image data Db, and combined image data Dc, respectively. FIGS. 21(d) and 21(e) show examples of the image processing control signal Dbs. The image data Da shown in FIG. 21(a) represent a scenery image; the image data Db shown in FIG. 21(b) represent text information. Combining these two image data generates the combined image data Dc shown in FIG. 21(c), in which text information is superimposed on scenery data. According to the image processing control signal QYS shown in FIG. 21(d), edge correction processing is not performed in the rectangular area indicated in white, being performed only in the area outside the white rectangular area. According to the image processing control signal shown in FIG. 21(e), edge correction processing is not performed in the text information area, but only in the area outside the text information area, that is, in the scenery image area.

The selectors 49, 52 in the edge width corrector 48 and edge enhancer 51 select the luminance data before and after the edge correction according to image processing control signals QYS like the ones shown in FIGS. 21(d) and 21(e), thereby preventing text information and the peripheral edges thereof from taking on an unnatural appearance due to unnecessary correction.

As described above, in the image processing apparatus according to the present embodiment, an arbitrary image including text or graphic information is combined with the image data, and while edge correction processing is performed on the combined image, an image processing control signal is generated that designates a specific area in the combined image. The corrected or uncorrected combined image data are selected and output, pixel by pixel, according to the image processing control signal, so that edges are corrected only in the necessary area.

### INDUSTRIAL APPLICABILITY

The image processing apparatus according to the present invention comprises an edge correction means for correcting edge widths in an image, an enhancement value calculation means for calculating enhancement values for enhancing edges according to a high frequency component of the image with the corrected edge widths, and an edge enhancement means for enhancing the edges by adding the enhancement values to the image with the corrected edge widths. Therefore, appropriate correction processing can be performed on edges having various different luminance variations to enhance image sharpness without overcorrection or undercorrection.

1. An image processing apparatus comprising:
a zoom ratio control means for detecting edges in image data and generating zoom ratio control values according to widths of the detected edges;
an edge correction means for correcting edge widths by carrying out an interpolation process on the image data according to the zoom ratio control values;
an enhancement value calculation means for detecting a high frequency component of the image data with the corrected edge widths and calculating enhancement values for enhancing the edges in the image data according to the detected high frequency component; and
an edge enhancement means for enhancing the edges in the image data by adding the enhancement values to the image data with the corrected edge widths.

2. The image processing apparatus of claim 1, wherein the zoom ratio control means generates the zoom ratio control values for each edge as positive values in a front part of the edge, negative values in a central part of the edge, and positive values in a rear part of the edge, the generated values summing to zero over the whole edge, and generates zoom conversion ratios by adding the zoom ratio control values to a reference zoom conversion ratio indicating an enlargement ratio or a reduction ratio of the image data, and the edge correction means carries out the interpolation process according to the zoom conversion ratios.

3. The image processing apparatus of claim 1, further comprising:
an image generating means for generating an image to be combined with the image data;
an image combining means for combining the image generated by the image generating means with the image data and outputting combined image data; and
a means for generating an image processing control signal designating a prescribed area in the combined image data; wherein
the edge correction means and the edge enhancing means carry out edge width correction and edge enhancement only in the area designated by the image processing control signal.

4. An image processing method comprising:
a step of detecting edges in image data and generating zoom ratio control values according to edge widths of the detected edges;
a step of correcting the edge widths by carrying out an interpolation process on the image data according to the zoom ratio control values;
a step of detecting a high frequency component in the image data with corrected edge widths and calculating enhancement values for enhancing the edges in the image data according to the detected high frequency component; and
a step of enhancing the edges in the image data by adding the enhancement values to the image data with the corrected edge widths.

5. The image processing method of claim 4, wherein the zoom ratio control values for each edge are generated as positive values in a front part of the edge, negative values in a central part of the edge, and positive values in a rear part of the edge, the generated values summing to zero over the whole edge, further comprising a step of generating zoom conversion ratios by adding the zoom ratio control values to a reference zoom conversion ratio indicating an enlargement ratio or a reduction ratio of the image data, the interpolation process being carried out according to the zoom conversion ratios.

6. The image processing method of claim 4, further comprising:
a step of generating an image to be combined with the image data;
a step of outputting combined image data in which the image is combined with the image data; and
a step of generating an image processing control signal designating a prescribed area in the combined image data; wherein
edge width correction and edge enhancement are carried out only in the area designated by the image processing control signal.

7. An image processing apparatus comprising:
a conversion means for receiving image data and converting the image data to luminance data and color difference data;
a frame memory control means for writing the luminance data and the color difference data into a frame memory, and reading the written luminance data and the written color difference data from the frame memory at prescribed timings;
a means for extracting data for a plurality of vertically aligned pixels from the luminance data read from of the frame memory;
a zoom ratio control means for detecting edges from the data for the plurality of vertically aligned pixels, and generating vertical zoom ratio control values according to edge widths of the detected edges; and
an edge width correction means for carrying out an interpolation process on the luminance data according to the vertical zoom ratio control values, thereby correcting vertical edge widths; wherein
the frame memory control means reads the color difference data with a delay from the luminance data of at least an interval required for the vertical edge width correction.

8. The image processing apparatus of claim 7, further comprising:
an enhancement value calculation means for detecting a high frequency component in the luminance data with the corrected vertical edge widths and calculating enhancement values for vertically enhancing edges in the luminance data according to the detected high frequency component; and
an edge enhancement means for vertically enhancing the edges in the luminance data by adding the enhancement values to the luminance data with the corrected vertical edge widths; wherein
the frame memory control means reads the color difference data with a delay from the luminance data of at least an interval required for the vertical edge width correction and edge enhancement.

9. The image processing apparatus of claim 7, comprising:
a means for extracting data for a plurality of horizontally aligned pixels from the luminance data read from the frame memory;
a zoom ratio control means for detecting edges from the data for the plurality of horizontally aligned pixels, and generating horizontal zoom ratio control values according to edge widths of the detected edges; and
an edge width correction means for correcting horizontal edge widths by carrying out an interpolation process on the luminance data according to the horizontal zoom ratio control values.

10. The image processing apparatus of claim 9, further comprising:
an enhancement value calculation means for detecting a high frequency component in the luminance data with corrected horizontal edge widths and generating enhancement values for horizontally enhancing the edges in the luminance data according to the detected high frequency component; and
an edge enhancement means for horizontally enhancing the edges in the luminance data by adding the enhancement values to the luminance data with the corrected horizontal edge widths.

11. An image display apparatus comprising the image processing apparatus of claim 1.

12. An image display apparatus comprising the image processing apparatus of claim 7.
